(19) United States
(12) Patent Application Publication
(10) Pub. No.: US 2026/0146313 A1
(43) Pub. Date: May 28, 2026

(54) System and Method For a Spatially-resolved Thin Film Linear Deposition

(71) Applicant: Jehad Abushama, San Jose, CA (US)

(72) Inventor: Jehad Abushama, San Jose, CA (US)

(21) Appl. No.: 19/372,208

(22) Filed: Oct. 28, 2025

Related U.S. Application Data
(60) Provisional application No. 63/712,894, filed on Oct. 28, 2024.

(51) Int. Cl. C23C 14/24; C23C 14/06; C23C 14/12; C23C 14/54

(52) U.S. Cl. CPC C23C 14/243; C23C 14/0694; C23C 14/12; C23C 14/548

(57) ABSTRACT

A vapor-deposition system is provided including one or more precursor chambers configured to deliver precursor material to a plurality of crucibles under vacuum conditions. Each crucible is independently heated to a controlled temperature to generate a vaporized precursor stream that is conveyed through a corresponding transfer tube and manifold to a nozzle array positioned above a substrate. Certain embodiments employ a single precursor chamber and multiple crucibles connected through a distribution assembly, while other embodiments include multiple manifolds arranged in parallel above the substrate. The system enables coordinated co-deposition of metallic, chalcogen, and dopant materials to form composition-controlled thin films with high spatial uniformity.

### INCORPORATION BY REFERENCE

This application is a non-provisional application of and claims the benefit of earlier filing date under 35 U.S.C. 119(e) to the filing date of U.S. Application No. 63/712,894, filed on 2024 Oct. 28, titled “Spatially-resolved high-temperature high-rate novel deposition processes for high-purity thin film materials,” the entirety of which is incorporated herein by reference.

### FIELD OF INVENTION

The present invention relates generally to thin-film deposition systems and methods, and more particularly to vapor delivery apparatuses for physical vapor deposition, chemical vapor deposition, and related coating processes. The invention concerns deposition systems and methods incorporating spatially-resolved manifolds and nozzle arrays configured to maximize and control flux distribution of vaporized source material across a substrate, thereby improving deposition uniformity, throughput, and efficiency.

### BACKGROUND

Thin-film deposition is a foundational process in modern manufacturing of semiconductors, flat-panel displays, photovoltaic cells, optical coatings, and numerous other electronic and optoelectronic devices. In such processes, a source material is vaporized and directed toward a substrate surface, where it condenses to form a thin film with desired structural, electrical, or optical properties. Techniques such as physical vapor deposition (PVD), chemical vapor deposition (CVD), molecular beam epitaxy (MBE), thermal evaporation, and sputtering have all been employed to achieve films of varying compositions and thicknesses. The ability to precisely control film thickness, composition, and uniformity directly impacts device performance, manufacturing yield, and cost efficiency.

Despite decades of development, deposition processes continue to face longstanding challenges in achieving uniform coverage across large or irregularly shaped substrates. One difficulty arises from the natural angular distribution of vapor flux. For instance, material evaporating from a point or line source tends to follow a cosine distribution, resulting in substantially higher flux near the normal axis and diminished flux at oblique angles. As substrate areas increase, this effect leads to thickness gradients and edge thinning. Additional non-uniformities may result from gas-phase scattering, shadowing by chamber hardware, turbulence or recirculation within the vapor stream, and temperature differentials across the substrate. These issues are compounded in high-throughput environments, where substrates may be translated continuously on conveyors or rotated within planetary systems, since averaging effects can only partially compensate for the underlying flux imbalance.

A number of strategies have been developed to address these non-uniformities. One approach relies on mechanical motion of the substrate, such as rotation, revolution, or linear translation, so that local variations in flux are averaged over time. While effective for small wafers or panels, such motion becomes cumbersome and less efficient for larger substrates or continuous-feed processes. Other methods employ physical baffles, shutters, or shadow masks to selectively block or redirect vapor. Although these can reshape the deposition profile, they often reduce overall flux efficiency and introduce new points of contamination or maintenance.

More recently, nozzle arrays and simple manifolding techniques have been used to channel vapor toward the substrate. These designs can distribute material more evenly than a single-point source, but they are typically limited to uniform or symmetric arrangements that do not fully counteract the inherent cosine distribution of vapor flux. Similarly, certain chemical vapor deposition systems attempt to enhance uniformity by using carrier gas streams to spread material, but such methods introduce additional variables in gas flow dynamics, pumping requirements, and precursor utilization efficiency.

Despite these developments, a persistent need remains for deposition systems that provide more precise, spatially resolved control over vapor flux distribution. In particular, it is desirable to move beyond purely mechanical averaging or passive masking approaches, and instead employ manifold and nozzle architectures that actively shape, regulate, and maximize vapor delivery across the substrate. Such improvements would allow for higher deposition uniformity, improved material utilization, and greater throughput without sacrificing scalability.

### OBJECTIVE OF THE INVENTION

It is an object of the present invention to provide a spatially-resolved thermal evaporation thin-film deposition system.

It is another object of the present invention to provide a system configured to improve flux distribution uniformity across a substrate.

It is a further object of the present invention to provide a system that maximizes deposition throughput while maintaining precise film thickness control.

It is another object of the present invention to provide a system configured to achieve deposition cycle times on the order of about 10 minutes per run, or in certain embodiments ranging from about 3 minutes to about 20 minutes depending on process requirements.

It is yet another object of the present invention to provide a system that reduces material waste and improves source utilization efficiency.

It is a further object of the present invention to provide a system that achieves material utilization efficiencies greater than about 90%, and in some embodiments greater than about 95%.

It is still another object of the present invention to overcome scalability challenges in thin film manufacturing and provide a system that accommodates substrates of varying size, geometry, and motion (e.g., stationary or moving).

It is another object of the present invention to provide a system capable of depositing films in the thickness range of ≤4 μm, and in some embodiments from about 1.0 μm to about 3.0 μm.

It is a further object of the present invention to provide a system configured to maintain film thickness uniformity within about or better than ±(3-4)% across substrates having widths of about 1216 mm or greater, and within about or better than ±2% across smaller substrates, with substrate widths in some embodiments ranging from about 100 mm to about 2000 mm.

It is another object of the present invention to provide a system configured to operate at high vacuum pressures, including pressures in the range of about 10⁻⁶ to about 10⁻⁵ Torr, with acceptable leak rates of less than about 1×10⁻⁹ Torr·L/s, and with background gas temperatures of about 100° C. or less.

It is another object of the present invention to provide a system that may be scaled to industrial manufacturing environments while preserving uniformity and process repeatability.

It is a further object of the present invention to provide a system employing spatially-resolved manifolds and nozzle arrays configured to tailor flux distribution profiles.

It is another object of the present invention to provide a system adaptable for use with a wide range of source materials, including metals, semiconductors, and organic compounds.

It is another object of the present invention to provide a system that improves reliability, reduces downtime, and simplifies maintenance relative to conventional thermal evaporation tools.

It is an object of the present invention to provide a method of spatially-resolved thermal evaporation thin-film deposition.

It is another object of the present invention to provide a method that improves flux distribution uniformity across a substrate.

It is a further object of the present invention to provide a method that maximizes deposition throughput while maintaining precise film thickness control.

It is yet another object of the present invention to provide a method that enables deposition runs to be completed in about 10 minutes, or in certain embodiments within a range of about 5 to about 20 minutes.

It is yet another object of the present invention to provide a method that reduces material waste and improves source utilization efficiency.

It is a further object of the present invention to provide a method that deposits more than about 90% of evaporated precursor material onto the substrate, and in some embodiments more than about 95%.

It is still another object of the present invention to provide a method that accommodates substrates of varying size, geometry, and motion (e.g., stationary or moving).

It is another object of the present invention to provide a method that achieves deposited film thicknesses in the range of ≤4 μm, and in some embodiments from about 1.0 μm to about 3.0 μm.

It is a further object of the present invention to provide a method that produces film uniformity within about or better than ±(3-4)% across substrates having widths of about 1216 mm or greater, and within about or better than ±2% across smaller substrates, with substrate widths in some embodiments ranging from about 100 mm to about 2000 mm.

It is another object of the present invention to provide a method that maintains deposition chamber conditions at vacuum pressures in the range of about 10 −6 to about 10⁻⁵ Torr, with leak rates below about 1×10⁻⁹ Torr·L/s, and background gas temperatures of about 100° C. or less.

It is another object of the present invention to provide a scalable method in thin film industrial manufacturing environments while preserving uniformity, process repeatability, process controllability, high performance, and cost efficiency.

It is a further object of the present invention to provide a method employing spatially-resolved manifolds and nozzle arrays configured to tailor flux distribution profiles.

It is another object of the present invention to provide a method adaptable for use with a wide range of source materials, including metals, semiconductors, and organic compounds.

It is another object of the present invention to provide a method that improves reliability, reduces downtime, and simplifies operation relative to conventional thermal evaporation techniques.

These and other objects of the present invention will become apparent to those skilled in the art from the following descriptions and accompanying drawings.

### SUMMARY OF THE INVENTION

The present invention is directed to spatially-resolved thin-film deposition systems and methods configured to improve uniformity, throughput, and material utilization efficiency in high-temperature vapor deposition processes. In certain embodiments, the system includes a feed-in subsystem for controlled delivery of precursor material, a crucible housing containing a crucible capable of operating at temperatures from ambient to ≥1600° C., and a transfer-tube/manifold assembly fluidly coupled to the crucible. A nozzle array is coupled to the manifold and configured to direct vaporized precursor material toward a substrate in a spatially resolved manner, thereby regulating vapor flux distribution across large-area and small-area substrates.

In some embodiments, the manifold is configured to operate within a temperature range of about 100° C. to ≥1600° C. depending on precursor chemistry and process requirements, with closed-loop feedback systems maintaining temperature stability within about ±0.5° C. Temperature gradients may be employed such that proximal regions adjacent the crucible are maintained at elevated temperatures (e.g., about 100 to ≥1600° C.) while distal nozzle-array regions are maintained at temperatures capable of maintaining the material evaporated in the crucible in vapor phase. These provisions minimize condensation within the vapor pathway while ensuring robust delivery of precursor material to the substrate.

In further embodiments, the system achieves film thickness uniformity within about or better than ±(3-4)% for substrates of about 1216 mm width and within about or better than ±2% for substrates of about 300 mm width. Film thicknesses may be ≤4 μm, and in some embodiments from about 1.0 μm to about 3.0 μm. Deposition cycle times may range from about 3 minutes to about 20 minutes per run, with substrate motion and nozzle arrangements tailored to specific process requirements. The system may be operated under vacuum pressures of about 10⁻⁶ to about 10⁻⁵ Torr, with chamber leak rates less than about 1×10⁻⁹ Torr·L/s and background gas temperatures of about 100° C. or less. These features provide improved material utilization efficiencies greater than about 90%, and in some embodiments greater than about 95%, while maintaining high throughput and scalability for thin-film industrial manufacturing.

In certain embodiments, the vapor-deposition system may include a single precursor chamber coupled to a plurality of crucibles operated at individually controlled temperatures and delivering vaporized materials through one or more transfer tubes and manifolds. In other embodiments, multiple crucibles may each connect to corresponding manifolds arranged in parallel above the substrate, enabling composition-controlled co-deposition and uniform film formation across the substrate plane.

### BRIEF DESCRIPTION

The present invention will be understood and appreciated more fully from the following detailed description taken in conjunction with the drawings in which:

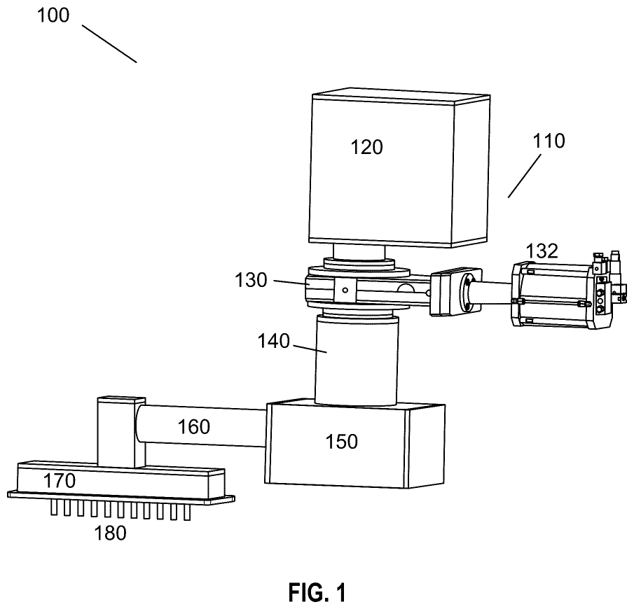

FIG. 1 is a perspective view of one embodiment of a top-mounted vapor deposition system including a feed-in subsystem, crucible housing, manifold, and nozzle array.

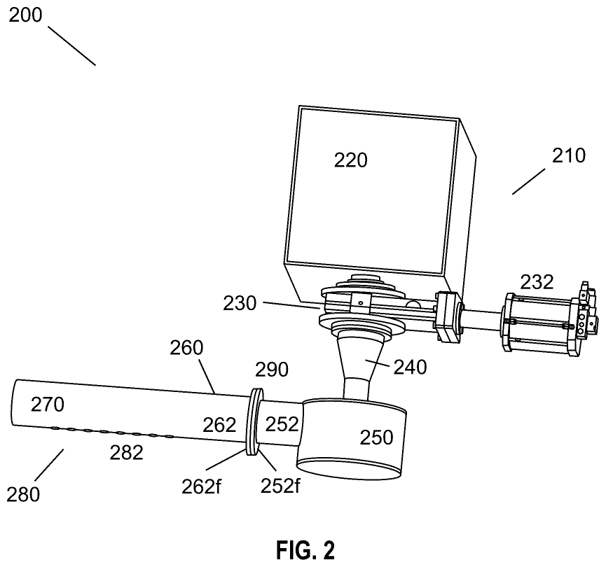

FIG. 2 is a perspective view of an alternative embodiment of a lateral vapor deposition system emphasizing the lateral manifold and nozzle array arrangement which is coupled to the crucible housing through a flange joint.

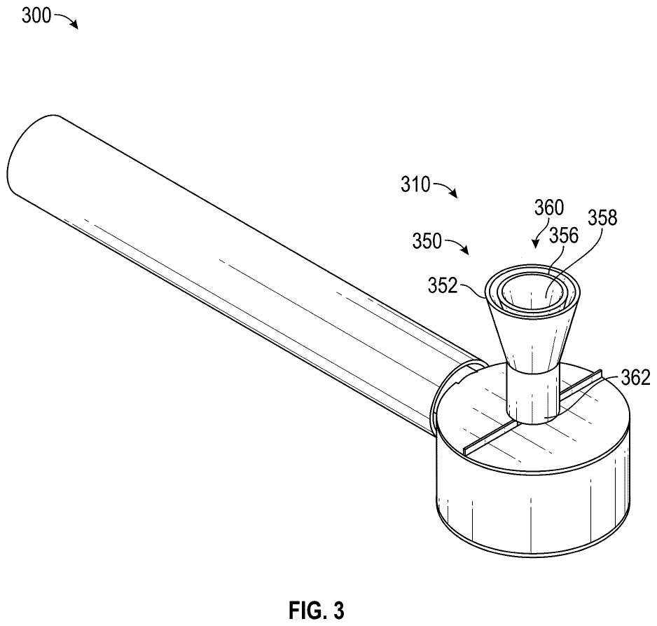

FIG. 3 is a sectional view illustrating a dual-layer funnel tube assembly with an outer structural jacket and an inner feed tube for precursor delivery.

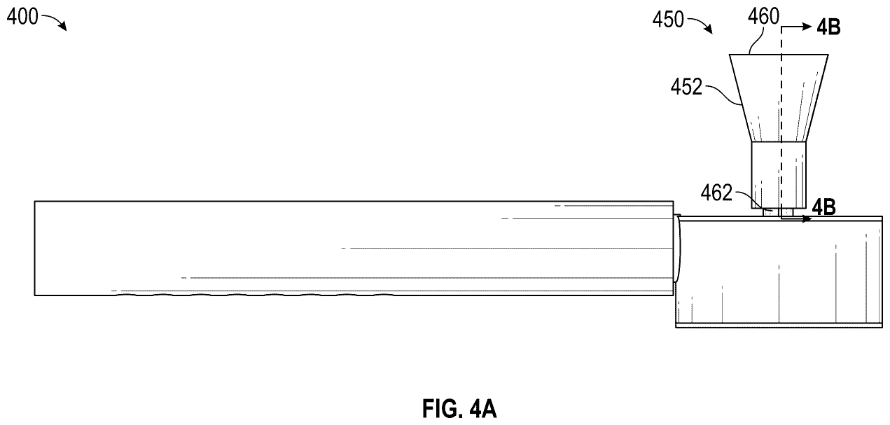

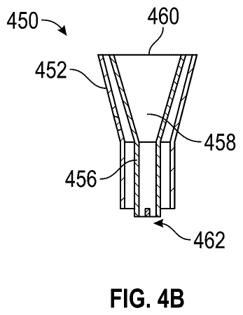

FIG. 4A is an external elevation view of a funnel tube assembly.

FIG. 4B is a cross-sectional view of the funnel tube of FIG. 4A showing its concentric dual-layer construction.

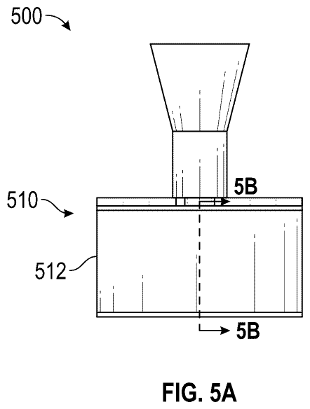

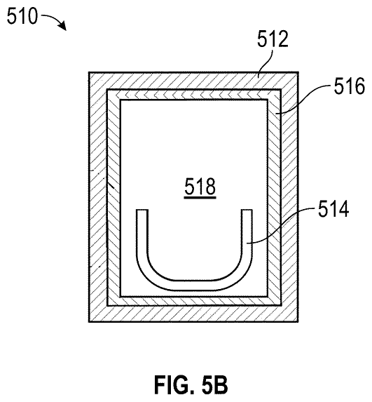

FIG. 5A is an external elevation view of a crucible housing adapted for high-temperature operation.

FIG. 5B is a cross-sectional view of the crucible housing of FIG. 5A showing the outer shell, insulating layer, and crucible.

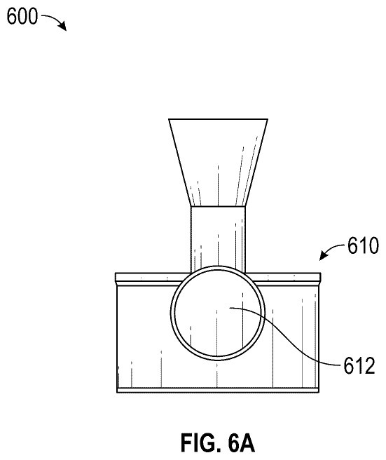

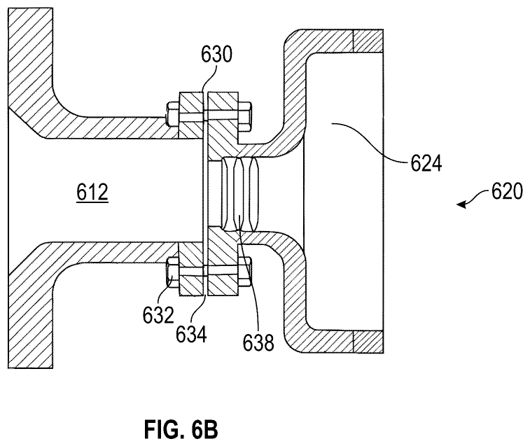

FIG. 6A is a schematic view of a transition assembly from a funnel tube assembly to a crucible housing and its outlet.

FIG. 6B is a sectional view of an exemplary flange joint of a crucible outlet and the downstream transfer tube.

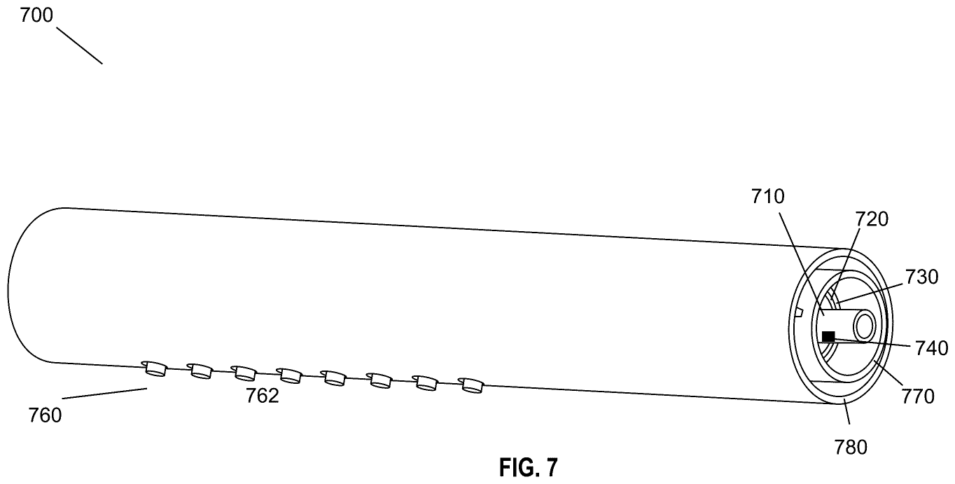

FIG. 7 is a perspective view of a multilayer heated transfer-tube/manifold assembly including a tube, heating element, insulating sleeve, thermocouple, nozzle array, inner shield, and cooling jacket.

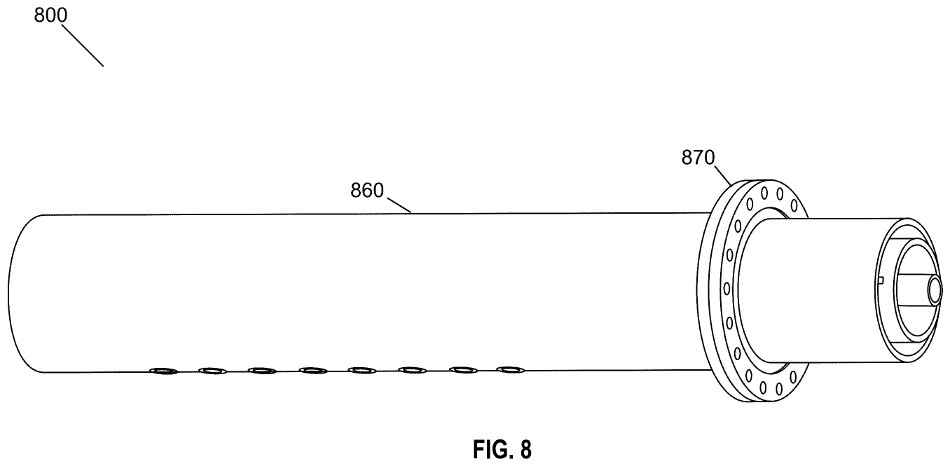

FIG. 8 is a perspective view of a transfer-tube/manifold assembly including an outer shield tube and a mounting flange joint configured to mount the cantilevered assembly and nozzle array to a crucible housing.

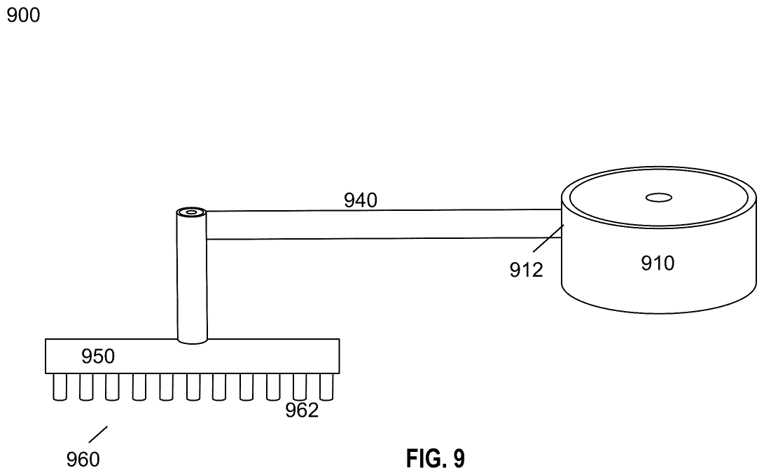

FIG. 9 is a schematic view of a crucible housing, and laterally oriented transfer tube coupled to a manifold and nozzle array.

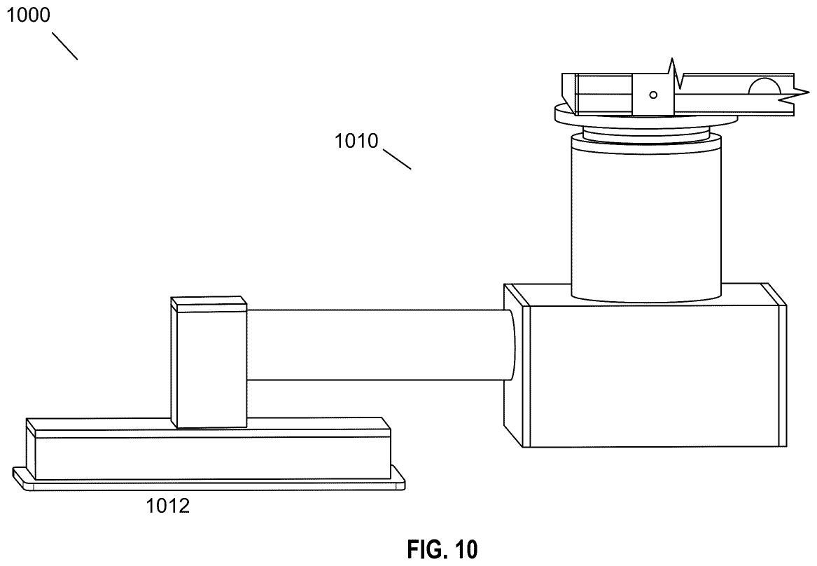

FIG. 10 is a perspective view of an external exoskeleton enclosing the vapor delivery subsystem, showing the flanged interface to a vacuum chamber and integrated cooling jackets.

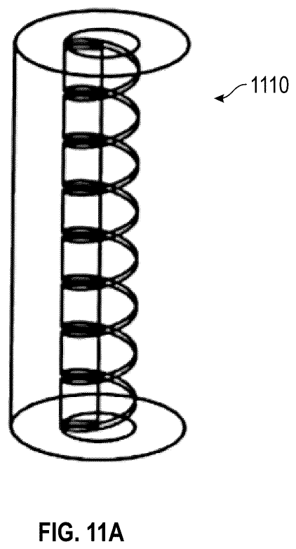

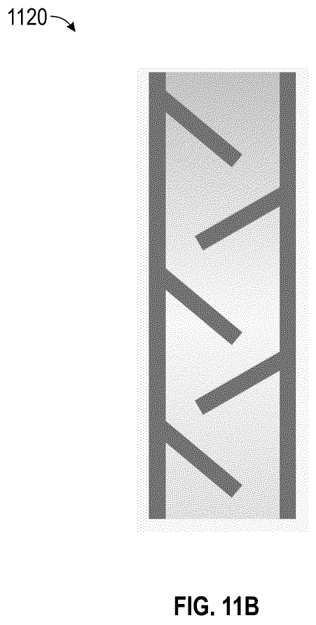

FIG. 11A is a schematic view of a vertical feed-in tube with a helical shielding structure.

FIG. 11B is a schematic view of a vertical feed-in tube with staggered inclined baffles.

FIG. 12 illustrates a dual-source deposition system having two crucibles and corresponding manifolds positioned above a common substrate.

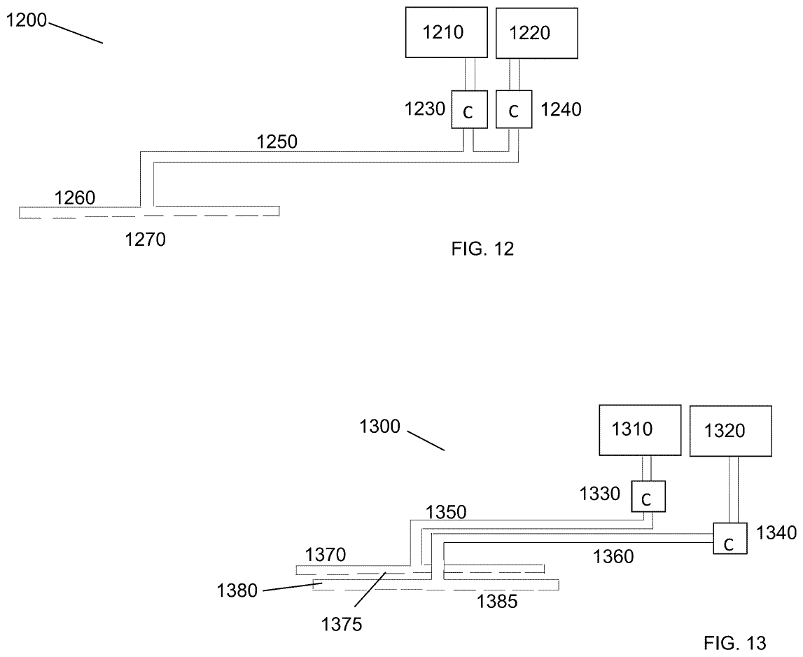

FIG. 13 illustrates a coordinated dual-path deposition system in which two vapor paths are centrally synchronized to produce mixed vapor flux on a single substrate.

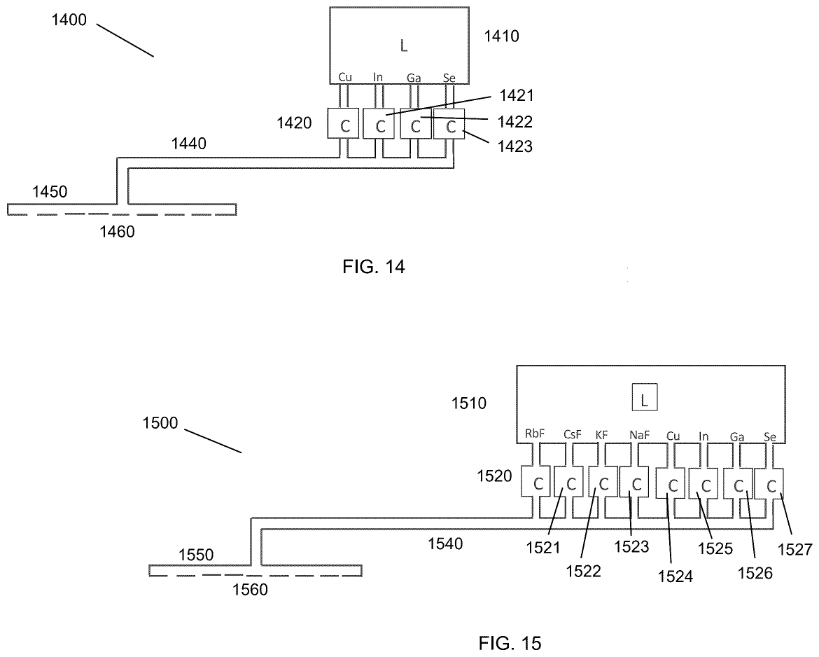

FIG. 14 illustrates a single-chamber, multi-crucible system in which multiple crucibles feed a common manifold through a distribution assembly.

FIG. 15 illustrates a similar single-chamber, multi-crucible system configured for dopant introduction and composition control.

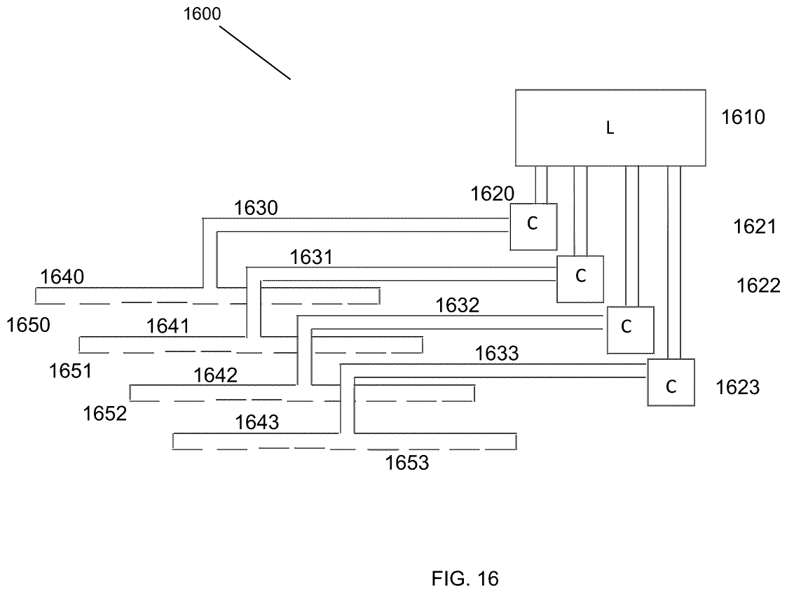

FIG. 16 illustrates a multi-manifold configuration in which multiple crucibles each supply a corresponding manifold for simultaneous or sequential co-deposition.

### DETAILED DESCRIPTION

The present invention will be described in the context of preferred embodiments.

The following detailed description is provided to enable any person skilled in the art to make and use the claimed invention and sets forth the best mode contemplated by the inventors for carrying out the invention. The description is presented in the context of particular embodiments and applications, and is not intended to be exhaustive or to limit the invention to the precise forms disclosed. Rather, it will be apparent to those skilled in the art that various modifications and equivalent arrangements can be made without departing from the spirit and scope of the invention.

Where the description refers to elements in singular form, it is to be understood that such reference includes plural embodiments as well, unless the context clearly dictates otherwise. Likewise, directional or positional terms such as “top,” “bottom,” “above,” “below,” “front,” “back,” and the like are used for convenience in describing embodiments relative to the figures, and are not intended to limit the invention to any particular orientation.

Reference throughout this specification to “one embodiment,” “an embodiment,” “certain embodiments,” or similar expressions means that a particular feature, structure, or characteristic described in connection with the embodiment is included in at least one embodiment of the invention. Thus, the appearances of such phrases in various places throughout this specification are not necessarily referring to the same embodiment. Furthermore, the described features, structures, or characteristics may be combined in any suitable manner in one or more embodiments.

The drawings are intended to illustrate certain embodiments of the invention, and together with the written description, serve to explain principles of the invention. It is to be understood that the drawings are schematic in nature and not necessarily to scale.

Referring now to FIG. 1, an exemplary embodiment 100 of a top-mounted thin-film deposition system of the present invention is illustrated. The system may include a feed-in subsystem 110 configured to convey precursor material into a crucible 150 for vaporization. The feed-in subsystem 110 may comprise a feed-in chamber 120 positioned at an upper portion of the assembly, the chamber being adapted to receive precursor material. In certain embodiments, the feed-in chamber 120 may house a volumetric screw or vibratory feeder capable of metering precursor material in a controlled manner. The screw or vibratory feeder may be specially designed and arranged in the present invention, with its specialized features described in greater detail hereinafter. In certain embodiments, the feed-in chamber may provide a total volume of about 2000 cc with liner and a net capacity of about 1200 cc when configured for a 300 mm wide substrate. In other embodiments, the feed-in chamber may provide about 8000 cc with liner and a net capacity of about 4800 cc when configured for a 1216 mm wide substrate. Other chamber volumes and configurations may also be employed depending on substrate dimensions and throughput requirements. The feed-in chamber may be reloaded with precursor material as needed, since the loading zone is isolated from the crucible and manifold and may be vented or accessed without disrupting vacuum integrity downstream.

A high-temperature vacuum valve 130, actuated by a lateral actuator 132, such as a pneumatic or electromechanical drive unit for precise opening and closing control, may be disposed below the feed-in chamber 120 to selectively permit or restrict material flow while maintaining vacuum integrity. A vertical funnel tube 140 may extend below the valve 130 to direct precursor material into the crucible housing 150. In certain embodiments, the valve 130 may be realized as a commercially available high-temperature vacuum valve, such as those supplied by VAT, and the illustrated configuration represents an example of such a component integrated into the feed-in subsystem. The volumetric screw or vibratory feeder may be configured to deliver precursor material at a feed rate dependent upon material density and particle size; in certain embodiments, feed rates may be on the order of several grams per minute, scalable according to the deposition material employed.

The crucible housing 150 may contain a crucible configured to vaporize precursor material at temperatures ranging from ambient to ≥1600° C. The crucible housing 150 may be coupled to a transfer tube 160 configured to convey vaporized precursor material toward a manifold 170. The manifold 170 may be heated along its length to avoid condensation and may include internal passages to guide vapor flow uniformly into a nozzle array 180. The nozzle array 180 may comprise multiple outlets arranged in a spatially resolved configuration to distribute vapor flux across a substrate surface with improved uniformity and controllability.

Accordingly, the embodiment depicted in FIG. 1 illustrates a top-mounted arrangement in which the feed-in subsystem 110, crucible 150, transfer tube 160, manifold 170, and nozzle array 180 are integrated to deliver a spatially resolved vapor flux suitable for thin-film deposition processes at high temperature. In certain embodiments, the system may be configured to complete a deposition cycle in ≤10 minutes.

Referring now to FIG. 2, an alternative embodiment 200 of the thin-film deposition system of the present invention is illustrated, emphasizing a configuration that incorporates a laterally extending assembly of transfer tube, manifold, and nozzle array. In this embodiment, precursor material may be introduced through a feed-in subsystem 210, including a feed-in chamber 220 coupled to a high-temperature valve 230 and an actuator 232. The valve 230 may be actuated by the actuator 232 mounted laterally to the valve body, thereby permitting or restricting precursor flow while maintaining vacuum integrity. A funnel tube 240 is positioned below the valve and configured to direct precursor material into a crucible housing 250, within which the material is vaporized at temperatures ranging from ambient to ≥1600° C.

The crucible housing 250 may be joined to a lateral transfer tube 260 and manifold 270 that project outward from the housing. In certain embodiments, the connection between the crucible housing 250 and the transfer-tube/manifold assembly may include a flange joint 290 comprising opposed flange surfaces, one flange incorporating a projecting spigot received in a corresponding recess of the mating flange. A metallic gasket, such as copper or nickel, may be positioned between the flange faces and compressed by bolts or clamps, thereby maintaining vacuum integrity while permitting the transfer tube 260, manifold 270, and nozzle array 280 to extend laterally in a cantilevered orientation.

The transfer tube 260 may be heated along its length to maintain temperatures above the condensation threshold of the precursor vapor. The manifold 270 terminates in a nozzle array 280 comprising a plurality of outlets 282. These outlets may be arranged in a spatially resolved pattern configured to regulate vapor flux across a substrate. In some implementations, the outlet arrangement may counteract natural angular distribution of vapor and improve uniformity of deposition, particularly across large-area substrates or continuously moving substrates. Such spatial resolution of vapor distribution represents a feature of the present invention, enabling improved thin-film uniformity, deposition efficiency, and adaptability to varying substrate geometries. In certain embodiments, interchangeable nozzle modules may be provided, allowing variation in outlet geometries to adapt to different process requirements. In certain embodiments, the nozzle array and manifold arrangement may provide film thickness uniformity within about or better than ±(3-4)% across substrates having widths of about 1216 mm, and within about or better than ±2% across smaller substrates of about 300 mm. These values represent typical tolerance ranges achievable for large-area and smaller-area substrates, respectively, depending on chamber configuration and process requirements. In other embodiments, substrate widths may range from about 100 mm to about 2000 mm, depending on chamber configuration and process requirements. In still other embodiments, the substrate width may be at least about 500 mm, about 750 mm, about 1000 mm, about 1216 mm, or wider, with corresponding uniformity maintained within or better than about ±5%, about ±2%, or about ±0.5% depending on the scale of the substrate.

In certain embodiments, the crucible housing 250 and the immediately adjacent flow path are configured for vaporization temperatures of at least about 1400° C. The crucible, funnel throat, and a proximal section of the transfer tube may comprise refractory metals (e.g., molybdenum, tantalum, tungsten) and/or ceramic liners or coatings (e.g., alumina, yttria) to withstand and contain the elevated temperatures while maintaining chemical compatibility with the precursor. In further embodiments, internal surfaces may be coated with boron nitride or other protective surface treatments to resist attack by selenium or related chalcogen vapors, thereby extending component life under repeated deposition cycles. The manifold and nozzle array may be actively heated to a temperature above the condensation threshold of the vapor (depending on material). In further embodiments, a proximal transfer-tube segment or a refractory transition adapter adjacent to the crucible is maintained at a higher setpoint, dependent on the material being evaporated, while the distal nozzle-array region is maintained at temperatures capable of maintaining the material in vapor phase and preventing condensation within the nozzles. This axial gradient keeps the vapor above its condensation threshold.

In some implementations, the high-temperature zone is thermally isolated from temperature-sensitive components. The valve body may be disposed outside the hottest region and coupled to the funnel tube through a thermally isolating neck and radiant-heat shields, and the valve actuator may be mounted remotely via an extension shaft or bellows-sealed drive with intermediate heat sinks. The feed-in chamber may include standoffs and reflective shields to maintain chamber and feeder temperatures within vendor specifications.

In certain embodiments, the flange joint 290 between the crucible housing 250 and the lateral assembly of the transfer tube 260 and manifold 270, as illustrated in FIG. 2, is configured to operate as both a vacuum seal and a structural suspension for the laterally cantilevered transfer-tube/manifold assembly during high-temperature service exceeding about 1400° C. The joint may comprise a thick-walled crucible housing boss 252 with an integral radial flange 252f coupled to a mating transfer-tube hub 262 and its integral radial flange 262f. The hub may include a projecting spigot (not visible in FIG. 2) that engages a concentric counterbore of the housing boss to provide radial alignment and transfer of bending moments. A metallic gasket, such as a CF copper gasket or a metal C-seal, may be compressed between the flange faces to establish vacuum integrity, while water-cooled or air-cooled collars and thermal break features adjacent the sealing region may maintain gasket temperatures within allowable limits despite elevated crucible conditions. Axial bolt preload applied through high-temperature alloy studs may generate sufficient face friction to transmit bending moments from the manifold into the crucible housing, while the spigot simultaneously carries transverse shear and limits joint deflection. In some implementations, a short high-temperature bellows may be incorporated at the joint to accommodate differential thermal expansion between the crucible housing and the lateral manifold, in which case an external hanger or yoke may be employed to carry static weight while preserving vacuum integrity.

Referring now to FIG. 3, an embodiment 300 is shown that illustrates in greater detail the feed-in subsystem of the invention. In this embodiment, precursor material may be introduced into a feed-in assembly 310 comprising a vertically oriented funnel tube 350 that conveys material downward into an associated crucible. The funnel tube 350 may be constructed as a dual-layer structure including an inner feed tube 356 defining a central feed channel 358 and an outer structural jacket 352 that provides mechanical rigidity and alignment stability. The outer structural jacket 352 may comprise stainless steel or another high-strength alloy capable of maintaining vacuum and structural integrity during operation. The inner feed tube 356 may be formed of a material selected for chemical compatibility with the precursor, such as stainless steel, quartz, graphite, or other corrosion-resistant materials, and may have a smooth internal surface to minimize adhesion or bridging of precursor particles. The funnel tube 350 is not an intentionally heated component; however, it is designed so that powders, liquids, or small solid precursor pieces pass freely through to the crucible while preventing heat and vapors from the crucible from reflecting back into the feed-in subsystem. In certain embodiment, the lower end of the funnel tube 350 is spaced slightly above the crucible inlet to establish a thermal break that reduces conductive and radiative heat transfer. In another embodiment, one or more reflective collars or ceramic standoffs may also be employed around the junction to block radiant energy from the crucible region. In certain embodiments, the funnel tube 350 may have a length greater than about 6 inches and an internal diameter greater than about 1 inch, with dimensions scaled according to the desired feed rate and substrate size. This configuration allows the feed-in subsystem to remain unheated, structurally rigid, and thermally isolated from the high-temperature crucible region. In operation, precursor material may be received at an inlet 360 of the funnel tube 350, descend through the feed channel 358, and exit at an outlet 362 (not visible) aligned to the crucible region. The funnel tube 350 permits free passage of powders, liquids, or small solid precursor pieces while remaining unheated and thermally isolated from the high-temperature crucible region below.

The funnel tube 350 is unheated and configured to permit free flow of precursor material while preventing upward heat reflection. In some implementations, the liner 356 may be removably mounted to permit cleaning or replacement depending on the chemistry of the precursor material. The dual-layer funnel tube 350 thereby provides mechanical stability and contamination-free delivery of precursor material into the crucible for subsequent vaporization. In some implementations, a gentle inert-gas purge may be introduced through the funnel tube 350 or around the outlet 362 to prevent upward migration of vapor and to minimize particle deposition near the opening. The inner feed tube 356 may be removably mounted to permit cleaning or replacement depending on the chemistry of the precursor material. The simplified dual-layer construction thereby provides mechanical stability, chemical cleanliness, and unobstructed delivery of precursor material into the crucible while effectively blocking reverse heat flow or vapor reflection.

These provisions allow the system to achieve ambient to ≥1400° C. vaporization within the crucible region while preserving vacuum integrity, maintaining structural support for the downstream transfer tube, manifold and nozzle array, and ensuring reliable material delivery from the feed-in subsystem. The unheated and thermally isolated funnel tube 350 of FIG. 3 thus enables stable, contamination-free transfer of precursor material into the crucible under conditions that prevent back-reflection of heat and vapor into the feed-in chamber or valve region. In certain embodiments, the deposition process may achieve film thicknesses in the range of about ≤4 μm.

Referring now to FIG. 4A, an embodiment 400 is shown depicting an external elevation view of a feed-in assembly of the invention. In this embodiment, a funnel tube 450 is arranged vertically to direct precursor material toward an underlying crucible region. The funnel tube 450 may include an inlet 460 at its upper end and an outlet 462 at its lower end, the outlet being positioned in alignment with the crucible housing. In certain embodiments, the funnel tube 450 is coupled to a high-temperature valve and actuator system (not visible in FIG. 4A; disclosed in detail in FIGS. 1-2), which selectively permits or restricts precursor material flow while maintaining vacuum integrity. The exterior view of FIG. 4A illustrates the overall geometry and dimensional profile of the funnel tube 450, including its layered construction and external structural jacket 452 that provides cooling jacket mechanical support and rigidity.

Referring now to FIG. 4B, a cross-sectional view of the funnel tube 450 of FIG. 4A is illustrated. As shown, the funnel tube 450 comprises a concentric dual-layer arrangement including an outer structural jacket 452 and an inner feed tube 456 defining a central feed channel 458 that extends between an inlet 460 and an outlet 462. The outer jacket 452 may be fabricated from stainless steel or another high-strength alloy to provide rigidity and alignment stability under vacuum conditions. The inner feed tube 456 may be formed of a chemically compatible material such as stainless steel, quartz, graphite, or another corrosion-resistant metal or ceramic, and may include a smooth, low-adhesion surface to ensure uninterrupted flow of powdered, liquid, or pelletized precursor material into the crucible region. The funnel tube 450 is not an intentionally heated component and contains no insulating or resistive layers. Instead, its geometry and spacing relative to the crucible inlet are configured to minimize upward reflection of heat or vapor from the crucible while maintaining mechanical stability.

In certain embodiments, one or more reflective collars or shields may be positioned around the lower portion of the funnel tube 450 or the crucible inlet to redirect radiant energy away from the feed channel 458. The funnel tube 450 may further be supported by ceramic standoffs or low-conductivity brackets that reduce conductive heat transfer from the crucible housing. In some implementations, a gentle inert-gas purge may be introduced through or around the outlet 462 to discourage upward vapor migration and particle deposition. The inner feed tube 456 may be removably secured within the outer jacket 452, permitting inspection, cleaning, or replacement depending on precursor chemistry. The cross-sectional illustration of FIG. 4B thereby demonstrates the simplified dual-layer construction of the funnel tube 450, which provides structural integrity, smooth material flow, and passive thermal isolation consistent with the system-level embodiments described in FIGS. 1-3.

Referring now to FIG. 5A, an embodiment 500 is shown illustrating an external crucible housing configured for high-temperature vaporization of precursor material. The crucible housing 510 may comprise an outer shell 512 that provides mechanical containment and vacuum compatibility, while accommodating an internal crucible 514 (visible in FIG. 5B) arranged to receive and retain precursor material. The crucible 514 may be formed of graphite or refractory metals such as molybdenum, tantalum, or tungsten, or ceramic materials such as alumina, yttria, or boron nitride, capable of withstanding temperatures exceeding about 1400° C. The crucible 514 may be heated resistively—either directly by passing electrical current through the crucible body (in the case of graphite or refractory metals) or indirectly by surrounding the crucible with a resistive heater formed of graphite, refractory metal, or carbon-fiber elements. The crucible housing 510 may further include flange or collar features adapted for coupling to the upstream funnel tube and the downstream transfer-tube/manifold assembly described in FIGS. 1-4B.

Referring now to FIG. 5B, a cross-sectional view of the crucible housing 510 is shown, illustrating its multi-layer internal configuration. As depicted, the crucible housing 510 may comprise an outer shell 512 fabricated from stainless steel or high-strength alloy to provide vacuum boundary integrity. Disposed inward of the outer shell 512, an intermediate insulating layer 516 may be arranged circumferentially about the crucible 514. The insulating layer 516 may include refractory metal or ceramic, fibrous, or composite insulation adapted to limit conductive and radiative heat loss from the crucible 514 during operation. The crucible 514 itself defines a cavity region 518 in which precursor material is received from the feed-in funnel and subsequently vaporized.

In certain embodiments, the insulating layer 516 may further accommodate embedded heating elements configured to maintain the crucible 514 at or above vaporization temperature while preserving thermal isolation from the outer shell 512. The heating elements may include resistive coils, cartridge heaters, or induction coils depending on material selection and process requirements. In some implementations, the crucible 514 may be supported by a liner or cradle structure within the insulating layer 516, the liner being fabricated from compatible refractory material to prevent contamination. The cross-sectional arrangement shown in FIG. 5B thereby illustrates the cooperative relationship of outer shell 512, insulating layer 516, and crucible 514 to achieve stable, high-temperature vaporization within the disclosed thin-film deposition system.

In further embodiments, ports or apertures may be incorporated into the outer shell 512 for thermocouples, gas inlets, or viewing windows to monitor crucible conditions. Cooling jackets may be coupled to the outer shell 512 to dissipate excess heat and maintain acceptable wall temperatures. The crucible 514 may be removable, enabling replacement for different chemistries or after prolonged thermal cycling. This modular crucible housing 510 of FIGS. 5A-5B thereby provides durable, thermally insulated containment of precursor material, forming an essential component of the system previously disclosed in FIGS. 1-4.

Referring now to FIG. 6A, an embodiment 600 is shown that illustrates in greater detail a transition assembly between a crucible housing and a downstream transfer-tube/manifold assembly, corresponding generally to the region previously described with respect to FIG. 2. In this embodiment, a crucible housing 610 configured to contain a high-temperature crucible is coupled to a transfer-tube inlet section in a similar and consistent manner as disclosed in FIG. 2. The crucible housing 610 may terminate in an outlet port 612 aligned with the vaporization cavity of the crucible, the outlet port 612 being dimensioned to permit uniform discharge of vaporized precursor material. The transfer-tube inlet section is positioned in fluid communication with the outlet port 612, thereby receiving vaporized material and directing it through the transfer tube toward the downstream manifold passages.

In certain embodiments, the coupling between the crucible housing 610 and the transfer-tube inlet may be realized by a flange joint corresponding functionally to the flange joint 290 of FIG. 2. Here, the flange joint may comprise opposed radial flange surfaces compressed against a metallic gasket to maintain vacuum integrity. The flange joint may further incorporate alignment features such as a projecting spigot or concentric recess to provide accurate registration of the transfer-tube inlet with respect to the crucible outlet 612, similar to the spigot and counterbore alignment described for the crucible boss 252 and the adjoining flange structure in FIG. 2. High-temperature alloy studs or clamps may be employed to sustain bolt preload and to transmit mechanical loads arising from the weight of the transfer-tube/manifold assembly. In some implementations, thermal-isolation collars or cooled bosses may be included adjacent to the gasket to maintain sealing temperatures within allowable limits despite crucible operation temperatures exceeding about 1400° C. Thermal shields may also be employed around the transition region to protect adjacent structures from radiant heating by the crucible housing 610.

As illustrated in FIG. 6B, the flange joint 630 is depicted as a set of opposed radial flanges compressed together with bolts 632 and a gasket interface 634 therebetween. The joint 630 serves to couple the crucible housing 610 with the transfer-tube inlet 620 while preserving vacuum integrity. Adjacent to the joint, a bellows section 638 is shown, configured to accommodate differential thermal expansion between the crucible housing 610 and the transfer-tube/manifold assembly. Thermal shields may also be disposed proximate to the joint, positioned to protect the sealing region and adjacent structures from radiative heating.

In some implementations, a short bellows section 638 may be incorporated into the joint 630 to accommodate differential thermal expansion between the crucible housing 610 and the transfer-tube inlet 620. Where such a bellows is employed, an external hanger or yoke may be coupled to the transfer-tube/manifold assembly to support static weight while allowing compliant movement at the joint. These provisions correspond to the thermal-expansion and load-bearing strategies described with respect to FIG. 2, while being shown in greater structural detail in FIGS. 6A-6B.

The transfer-tube inlet 620 may be constructed as an integral hub defining one or more internal flow passages that distribute vaporized material into the downstream manifold body. The inlet geometry may be configured to reduce turbulence, avoid stagnation, and ensure uniform entry of vaporized material into the manifold network. In certain embodiments, heaters 624 may be disposed about the transfer-tube or manifold inlet region to maintain temperatures above the condensation threshold of the vapor.

Accordingly, the transition assembly of FIGS. 6A-6B establishes a robust and thermally managed interface between the crucible housing 610 and the transfer-tube/manifold assembly 620. This configuration permits vaporized precursor material generated in the crucible to be efficiently transferred through the transfer tube into the manifold passages without condensation or leakage, thereby providing a stable inlet condition for the manifold system. The transition assembly complements the crucible arrangements of FIGS. 5A-5B and directly precedes the manifold and nozzle arrangements previously described with respect to FIGS. 1-2. In certain embodiments, the system may be configured to achieve material-utilization efficiencies greater than about 90%.

Referring now to FIG. 7, an embodiment 700 illustrates a multilayer heated transfer-tube/manifold assembly that receives vaporized precursor material from the transition assembly of FIGS. 6A-6B and delivers it to a spatially resolved nozzle array under high-temperature operating conditions. The assembly may include a hollow cylindrical tube 710 forming a continuous internal flow passage that extends from a proximal transfer-tube region to a distal manifold plenum region. The tube 710 may be fabricated from refractory material such as molybdenum, tungsten, graphite, boron nitride, alumina, or combinations thereof. In certain embodiments, the tube 710 may comprise pyrolytic boron nitride (PBN), coated graphite, mullite, alumina, zirconia, or aluminum nitride. In some cases, ceramic components such as alumina or zirconia may be fabricated by advanced forming methods, including additive manufacturing or three-dimensional printing, to achieve complex internal geometries. In further embodiments, refractory metals such as molybdenum, tungsten, or tantalum with corrosion-resistant coatings may be used for the tube 710. The tube 710 is configured to withstand temperatures exceeding about 1400° C. without chemical reaction with source materials including copper, indium, gallium, selenium, silver, or sulfur. In practice, the assembly may be operated at temperatures ranging from about 100° C. to ≥1600° C. depending on the precursor materials and process requirements, under closed-loop temperature control to avoid condensation. In modeled cases, the continuous tube 710 was analyzed at about 1600° C., while in other implementations, operation may occur at about 1300° C., about 1000° C., or at lower temperatures such as below about 500° C. A proximal transition segment may be maintained at higher temperature, while the distal plenum and nozzle-array regions are maintained at temperatures sufficient to prevent condensation. This range of operating conditions allows flexibility for different materials systems while avoiding condensation. In further embodiments, temperature regulation may be achieved through a closed-loop feedback control system having an accuracy of about ±0.5° C., with response times sufficient to maintain stable vaporization conditions.

Surrounding the tube 710 is an electrically insulating sleeve 720, formed for example of boron nitride or alumina, which prevents electrical contact. Surrounding the insulating sleeve 720 is a resistive heating element 730 fabricated from graphite or refractory metal. By passing electrical current through the heating element 730, the tube 710 is heated along its length to maintain a temperature sufficient to keep vaporized precursor material in the vapor phase. Temperature may be monitored by a thermocouple 740 in contact with the tube 710, and a power-supply controller may regulate current through the heating element 730 in a closed-loop feedback system.

Integrated along the lower wall of the manifold-plenum portion of the tube 710 is a nozzle array 760 comprising a distributed set of vapor outlets 762. Each nozzle 762 may be a hollow insert or threaded element mated to a corresponding opening in the lower wall of the plenum, forming a vapor-tight joint that directs vaporized precursor material through the outlet only. The spatial arrangement of the nozzles 762—including number, density, and diameter—may be determined by vapor-flux modeling to achieve uniform thin-film deposition. In some embodiments, nozzle distribution may be varied across the array such that edge regions include larger or more numerous nozzles, while central regions include fewer or smaller nozzles. In further embodiments, elongated slot-shaped nozzles may be employed instead of circular nozzles to spread vapor in a controlled flux profile. Nozzle axes may be oriented substantially perpendicular to the substrate or inclined relative thereto to tailor flux distribution. The continuous geometry of the tube 710 thereby enables direct delivery of vaporized material from the crucible through the transfer region into the plenum and nozzle array without separate junctions or dead volumes that could promote condensation. In certain embodiments, the crucible may be operated from ambient temperature up to about 1600° C. depending on the precursor material, including chalcopyrite or perovskite materials. The manifold temperature may be maintained sufficiently high to keep the vaporized precursor material in the vapor phase, thereby minimizing condensation, while the temperature difference between the crucible and manifold is controlled to remain below the threshold that would permit condensation.

As shown in FIG. 7, additional concentric layers may be incorporated around the tube 710 to provide thermal management. An inner shield layer 770, formed of refractory metal such as tungsten, tantalum, or molybdenum, may be positioned around the heating element 730 to reflect thermal radiation and reduce heat transfer to the outer layers. Surrounding the inner shield 770, an external cooling jacket 780 may be provided, formed of stainless steel or another robust high-temperature alloy. The cooling jacket 780 may include internal channels or passages through which water or other heat-transfer fluids are circulated to extract heat from the assembly, thereby protecting the surrounding structure and shielding the substrate beneath the nozzle array 760 from excessive radiative heating. In certain embodiments, one or more of the inner-shield, tube, or cooling-jacket surfaces may be coated with boron nitride or related anti-corrosion coatings to resist degradation by selenium-containing vapors. In some implementations, the cooling jacket 780 may circulate high-temperature heat-transfer fluids, while in other embodiments chilled water between about −20° C. and about 150° C. may be used. Coolant flow rates may exceed about 4 gallons per minute. The cooling system may be configured to maintain a temperature differential such that the crucible region operates above about 1400° C. while the outer surface of the manifold assembly remains below about 300° C. In some implementations, thermal isolation may achieve blocked heat fluxes greater than about 4.26×10⁵ W/m² between a surface at about 1500° C. and a region at about 300° C., corresponding to a reduction in radiative transfer of more than 96% as predicted by the Stefan-Boltzmann law.

In certain embodiments, the interior of the tube 710 may include a gradual expansion from the transfer-tube section to the manifold-plenum section, forming a single continuous volume in which the cross-sectional area increases toward the nozzle array 760. This geometry promotes pressure equalization along the plenum and uniform distribution of vaporized material to all nozzles 762 without turbulence or stagnation. Optional perforated baffles or porous inserts may be disposed within the plenum region to enhance lateral pressure uniformity while maintaining a smooth outer contour for the multilayer assembly.

Accordingly, the integrated transfer-tube/manifold assembly 700 of FIG. 7 illustrates a continuous multilayer structure in which the tube 710, insulating sleeve 720, resistive heating element 730, thermocouple 740, nozzle array 760 with nozzles 762, inner shield 770, and cooling jacket 780 operate together to provide a spatially resolved, high-temperature vapor-distribution system suitable for thin-film deposition processes at conditions exceeding about 1400° C.

Referring now to FIG. 8, an embodiment 800 of the transfer-tube/manifold assembly is illustrated in which an outer shield tube 860 is integrated with a mounting flange 870 to provide both environmental protection and structural support. The outer shield tube 860 may be fabricated from a corrosion-resistant, high-temperature alloy such as Hastelloy and is configured to resist attack by reactive vapors including selenium. In certain embodiments, the outer shield tube 860 encloses the internal layers of the transfer-tube/manifold assembly, thereby protecting the resistive heating element, insulating sleeve, and cooling structures from the vacuum-chamber environment.

The outer shield tube 860 may also serve as a mechanical interface to the flange 870 positioned at the proximal end of the transfer-tube/manifold assembly. The flange 870 may be joined to a corresponding flange on the crucible housing or chamber wall, establishing both a vacuum seal and a rigid suspension for the assembly in a cantilevered orientation. In this arrangement, the flange 870 not only secures the assembly but also provides a robust load path to carry the weight of the transfer-tube/manifold assembly and nozzle array, and to withstand thermal cycling during operation above about 1400° C. This embodiment thus combines chemical durability, chamber integration, and mechanical robustness while preserving the spatially resolved vapor-delivery functions of the transfer-tube/manifold and nozzle-array system.

Referring now to FIG. 9, an embodiment 900 of the deposition source is illustrated, emphasizing the configuration of the crucible, transfer tube, and manifold assembly. The crucible housing 910 encloses a crucible, as previously described with respect to FIG. 5B, the crucible being configured as a hollow vessel formed of refractory material such as molybdenum, tungsten, tantalum, graphite, boron nitride, or alumina. In certain embodiments, the crucible may comprise coated graphite, pyrolytic boron nitride, or other high-temperature ceramic composites providing chemical compatibility with copper, indium, gallium, selenium, silver, sulfur, and related materials. The crucible may be cylindrical or rectangular-prismatic in form and closed at both top and bottom surfaces. The crucible may be heated by a resistive heating element (not pictured) to operating temperatures exceeding about 1400° C., thereby enabling vaporization of high-melting-point precursors such as copper, indium, gallium, selenium, silver, and sulfur. The crucible temperature may be regulated through a feedback loop that includes a high-temperature thermocouple in thermal contact with the crucible and a power supply delivering current to the heating element.

The crucible housing 910 includes a lateral outlet port 912 formed through a sidewall of the housing. The outlet port 912 is positioned in fluid communication with the crucible interior and is configured to discharge vaporized precursor material toward a transfer tube 940. The joint between the outlet port 912 and the transfer tube 940 may be realized by a threaded union, a spigot-and-gasket seal, or another high-vacuum, high-temperature connection. The transfer tube 940 is oriented laterally and joined to the outlet port 912 of the crucible housing in a vapor-tight manner. The transfer tube 940 may include resistive heating elements or be surrounded by a heater jacket to maintain temperatures above the condensation threshold along the vapor path from the crucible to the manifold 950.

In certain embodiments, the crucible may be surrounded by a resistive heating element (not shown in FIG. 9, but similar in function to the heating element described with respect to FIG. 7). The heating element may be formed of graphite or refractory metal and configured such that electrical current passing through it raises the crucible temperature to the desired vaporization range. The crucible temperature may be regulated by a feedback loop including a high-temperature thermocouple in thermal contact with the crucible and a power supply delivering current to the heating element, as described previously for the manifold-heating system in FIG. 7. This arrangement ensures that all precursor materials can be vaporized at high rates without condensation within the crucible chamber.

The transfer tube 940 couples to a lateral manifold 950 that distributes vaporized precursor material into a nozzle array 960. The transfer tube 940 may be formed of graphite, boron nitride, or other refractory material meeting the same temperature and chemical-compatibility requirements as the crucible. In certain embodiments, the transfer tube 940 may be encased in a resistive-heating layer similar to that described with respect to FIG. 7, ensuring that vaporized precursor material remains above condensation temperature throughout its path from the crucible to the manifold 950.

Accordingly, FIG. 9 illustrates how the crucible housing 910, transfer tube 940, manifold 950, and nozzle array 960 are integrated to form a continuous, high-temperature vapor path. The nozzle array 960 may comprise a plurality of nozzles 962, each configured as a hollow outlet for directing vapor toward a moving or stationary substrate. In certain embodiments, the nozzles 962 may be distributed in a spatially resolved pattern, including variations in density or diameter across the array to achieve uniform flux at the substrate. In some implementations, the nozzles 962 may be distributed non-uniformly across the array, such that edge regions include larger or more numerous nozzles while central regions include fewer or smaller nozzles, as described with respect to FIG. 7. In further embodiments, internal baffles or partitions may be incorporated within the manifold section of the transfer-tube/manifold assembly to promote pressure equalization or to meter vapor distribution along the length of the nozzle array 950. Such baffles may include perforated plates, porous inserts, or segmented flow passages that tailor the vapor-flux profile without disrupting the continuous outer structure of the assembly. In other embodiments, slot-shaped nozzles may be employed instead of circular nozzles to modify the spatial distribution of vapor flux. The combined arrangement of controlled internal flow features and spatially resolved nozzles thereby provides uniform and tunable deposition across a wide range of substrate widths and process conditions.

In certain embodiments, the distance from the exit of a nozzle 962 to the substrate surface may be about 200 mm for substrates having widths of about 1216 mm and about 75 mm for substrates having widths of about 300 mm. In other embodiments, these distances may be adjusted to accommodate different substrate sizes, process requirements, or chamber geometries while maintaining desired film uniformity. In some embodiments, deposition is performed at substrate-transport speeds of about 7 to 10 minutes per panel, corresponding to about 23 to 33 cm/min, depending on substrate dimensions. Substrate temperature during deposition may range from ambient to about 650° C., with temperature profiles selected to optimize thin-film growth for the particular material system. Substrates processed by the system may range in size from about 1216 mm×2300 mm×2.8 mm to about 300 mm×300 mm×2.8 mm, with other dimensions also supported depending on chamber design. In further embodiments, the nozzle array may include about 31 nozzles for a substrate width of about 1216 mm, each nozzle having a diameter of about 8 mm and spaced at about 40 mm intervals. For smaller substrates of about 300 mm width, the nozzle array may include about 11 nozzles, each nozzle having a diameter of about 3.5 mm and spaced at intervals of about 20 to 40 mm. In certain embodiments, the manifold-tube length may be about equal to the width of the substrate (e.g., about 1216 mm or about 300 mm), although longer or shorter manifold tubes may be employed depending on nozzle distribution and substrate distance. In some embodiments, the nozzles may be oriented substantially perpendicular to the substrate, while in other embodiments one or more nozzles may be angled relative to the substrate to tailor flux distribution. In further embodiments, the flux rate per nozzle may be about 0.1 g/s for a 1216 mm substrate width and about 0.007 g/s for a 300 mm substrate width, with other values and ranges depending on operating temperature and material. In certain embodiments, thickness uniformity across the substrate may be within about or better than ±(3-4)% for substrates of about 1216 mm width and within about or better than ±2% for substrates of about 300 mm width, consistent with the specifications described with respect to FIG. 2.

Referring now to FIG. 10, an embodiment 1000 of the deposition source system is illustrated in which an external sheathing, or exoskeleton 1010, encloses and supports the internal vapor delivery subsystem. The exoskeleton 1010 may be constructed of a robust, corrosion-resistant metal such as stainless steel, and is configured to withstand the pressure differential required to maintain vacuum conditions within the system. In this embodiment, the exoskeleton 1010 functions as both a structural support frame and as the vacuum boundary of the vapor delivery subsystem. By enclosing the internal crucible, transfer tube, manifold, and nozzle assemblies described in FIGS. 1-5, the exoskeleton 1010 ensures vacuum integrity while protecting the high-temperature components from direct exposure to the chamber environment.

At its lower section, the exoskeleton 1010 may be formed as a rectangular prism terminating in a flanged open bottom 1012 that is configured to mate with a corresponding flange on the vacuum chamber (not shown) through which the substrate is conveyed. This arrangement provides vacuum continuity between the deposition source and the chamber, while also creating a robust mechanical joint by which the exoskeleton 1010 suspends the internal vapor delivery system. In the top-mounted embodiment illustrated, the flange 1012 serves as the principal interface for chamber integration.

Because the internal components of the vapor delivery subsystem operate at elevated temperatures exceeding 1400° C., the exoskeleton 1010 may further incorporate cooling jackets (similar in function to the cooling jacket 780 described with respect to FIG. 7) integrated into its walls. The cooling jackets may include channels through which water or another high-temperature fluid is circulated to actively extract heat, thereby maintaining the external surfaces of the exoskeleton 1010 at safe operating temperatures despite the high internal thermal load. In certain embodiments, the cooling jackets may be formed as welded or machined passages within the exoskeleton walls, coupled to fluid inlets and outlets (not shown) for continuous cooling operation.

Accordingly, the embodiment of FIG. 10 illustrates an external sheathing 1010 that combines vacuum sealing, structural support, chamber integration, and active cooling. When considered together with the feed-in subsystem of FIG. 1, the lateral manifold configuration of FIG. 2, the transfer-tube/manifold assemblies of FIGS. 7-8, and the crucible/transfer path shown in FIG. 9, the embodiment of FIG. 10 demonstrates how an exoskeleton structure may be employed to enclose and support the entire vapor delivery system, ensuring robust operation at high temperature under vacuum conditions. In certain embodiments, the system may be operated at a vacuum pressure in the range of about 10⁻⁶ to about 10⁻⁵ Torr during deposition. In further embodiments, the acceptable leak rate of the chamber may be less than about 1×10⁻⁹ Torr·L/s, thereby preserving vacuum integrity during extended operation. In some implementations, the maximum permissible background gas temperature inside the chamber may be about 100° C., ensuring stability of thermal gradients while preventing contamination of the deposition process.

Referring now to FIGS. 11A and 11B, additional embodiments of the feed-in subsystem are illustrated, showing internal shielding geometries within the vertical feed-in tube. As previously described with respect to FIGS. 1 and 2, precursor material is introduced into the system through a feed-in chamber, which may contain a volumetric screw or vibratory feeder. In operation, with the high-temperature valve closed, the feed-in chamber is vented to atmosphere and precursor material is loaded into the volumetric screw or vibratory feeder through a hinged door (not pictured). The feed-in chamber is then evacuated to vacuum conditions using a mechanical pump coupled through a flange and vacuum tubing. Once the feed-in chamber has been pumped down, the high-temperature valve may be opened, and precursor material is metered out of the screw or vibratory feeder, passing through a flanged outlet at the chamber floor into the vertical funnel tube and feed-in tube. By gravity, the precursor material descends through the feed-in tube and into the crucible receptacle below. In certain embodiments, the internal shielding geometries such as helical structures or staggered baffles may extend along a feed-in tube length of greater than about 6 inches and an inner diameter of greater than about 1 inch, thereby ensuring adequate particle flow while maintaining effective thermal and vapor back flow shielding performance.

As illustrated in FIG. 11A, in one embodiment the internal geometry of the feed-in tube incorporates a helical shielding structure 1110 extending along the length of the tube interior. This helical element is configured such that precursor particles fall unimpeded downward by gravity, while the helical turns block or attenuate upward propagation of thermal radiation and precursor vapor from the crucible.

In another embodiment shown in FIG. 11B, the feed-in tube may incorporate a series of staggered inclined baffles 1120 machined into the inner wall. These baffles similarly allow downward passage of precursor solids, while obstructing upward flux of heat and vapor. Both embodiments serve to maintain a controlled thermal environment, protecting the valve and feed-in chamber from exposure to excessive heat and vapor flux while permitting continuous precursor loading during high-temperature operation.

The vertical feed-in tube is positioned above the crucible inlet to establish a thermal and radiative gap thereby impeding upward heat and vapor flow. Because the crucible operates at temperatures exceeding 1400° C., the feed-in tube and funnel tube are formed of refractory materials such as boron nitride, graphite, or mullite. In certain embodiments, the feed-in tube may also be fabricated from refractory metals such as molybdenum, tungsten, or tantalum, optionally with corrosion-resistant coatings such as boron nitride applied to internal surfaces to resist attack by selenium vapors. To maintain system integrity under these conditions, the feed-in tube and funnel tube may also be fitted with stainless steel cooling jackets (not pictured), through which water or a high-temperature fluid circulates to establish a thermal gradient between the crucible, which operates above 1400° C., and the high-temperature valve above, which must be maintained below approximately 300° C.

Accordingly, FIGS. 11A and 11B illustrate how internal geometries within the feed-in tube, including helical shielding structures 1110 and staggered incline baffles 1120, may be employed to achieve one-way precursor material flow under gravity while mitigating backflow of thermal radiation and vapor. When integrated with the feed-in subsystem of FIGS. 1-4B and the crucible/vapor distribution assemblies of FIGS. 6A-10, these features enable stable precursor delivery under vacuum conditions during high-temperature thin-film deposition processes.

As described in the preceding figures, vaporized precursor material is typically conveyed from each crucible through a single manifold and associated nozzle array directed toward the substrate. In subsequent embodiments, illustrated in FIGS. 12-16, the manifold architecture is progressively expanded to include two, four, or more manifolds arranged in parallel or series configurations. This modular approach permits independent control of vapor composition, flow rate, and temperature across multiple vapor paths, thereby enabling uniform or composition-graded thin-film formation over the substrate plane.

Referring now to FIGS. 12 and 13, further embodiments of the spatially-resolved vapor-deposition system are illustrated. These configurations extend the principles previously described with respect to FIGS. 1-11B, and in particular relate to systems employing multiple crucibles, transfer tube, manifold, and nozzle array assemblies configured to deliver distinct vaporized precursor materials to a common substrate surface. The embodiment of FIG. 12 illustrates a parallel-source architecture in which two precursor chambers supply two crucibles feeding separate manifolds that operate above a shared substrate. The embodiment of FIG. 13 illustrates a system with dual, fully independent vapor paths, each including its own precursor chamber, crucible, transfer tube, manifold, and nozzle array, enabling matched or differential deposition control across a single substrate.

In FIG. 12, an embodiment 1200 of a dual-source vapor-deposition system is shown. The system includes a first precursor chamber 1210 configured to receive and meter an alloy precursor mixture (for example, Cu—In—Ga) and a second precursor chamber 1220 configured to receive a selenium-based precursor. Each precursor chamber (1210, 1220) may include a volumetric or vibratory feeder to meter solid or pelletized feedstock into corresponding crucibles 1230 and 1240, which are disposed in high-temperature crucible housings. The crucibles may be formed of graphite, pyrolytic boron nitride, molybdenum, or other refractory materials and may be resistively heated to temperatures ranging from about ambient to ≥1600° C. depending on the respective precursor. In certain embodiments, the crucible 1230 is configured to vaporize a Cu-In-Ga alloy at about 1200-1400° C., while crucible 1240 vaporizes selenium at about 250-600° C. Each crucible may include thermal insulation and temperature-control feedback as described in earlier figures.

Vaporized precursor material exits each crucible through a transfer tube 1250 leading to a corresponding manifold 1260, which distributes the vapor through a nozzle array 1270 positioned above a substrate. The transfer tube 1250 and manifold 1260 may include internal resistive heating and temperature sensors configured to maintain the vapor above its condensation temperature during transport. The nozzle array 1270 is oriented substantially parallel to the substrate plane and spaced at a predetermined standoff distance to ensure uniform vapor-flux distribution across the substrate surface.

Accordingly, FIG. 12 illustrates a dual-source system in which two crucibles and manifolds operate in parallel above a single substrate to provide simultaneous co-deposition of distinct vapor species with independent flow and thermal regulation.

In FIG. 13, an embodiment 1300 is shown that employs two structurally distinct but centrally coordinated vapor-delivery assemblies. The system includes a first precursor chamber 1310 and a second precursor chamber 1320, each coupled respectively to crucibles 1330 and 1340. Each crucible receives a different precursor feed and is operated at a controlled temperature appropriate to its material—typically ranging from about ambient to ≥1600° C. for alloy sources and about 250-600° C. for selenium sources. Both vapor paths are governed by a common control unit that synchronizes feed rates, crucible temperatures, and flow parameters to maintain a predetermined vapor composition and ensure coordinated deposition behavior across the substrate.

Downstream of the crucibles, the first vapor path includes a transfer tube 1350 that conveys vaporized material from the first crucible 1330 to a manifold 1370, while the second vapor path includes a transfer tube 1360 that conveys vaporized material from the second crucible 1340 to a manifold 1380. Each manifold (1370, 1380) distributes its respective vapor through a nozzle array 1375 or 1385, the outlets of which are positioned above a common substrate plane. The nozzle arrays are oriented substantially parallel to each other and to the substrate, providing a spatially uniform vapor-flux distribution where the two vapor plumes intersect and mix directly on the substrate surface.

Each transfer tube (1350, 1360) and manifold (1370, 1380) may include independent temperature-control zones with closed-loop feedback coordinated through the central control system. This synchronized regulation maintains each vapor phase above its condensation temperature and stabilizes the local composition at the substrate interface. The control logic may further balance mass-flow ratios between the two vapor paths to achieve a desired compound stoichiometry during co-deposition.

Accordingly, FIG. 13 illustrates a dual-path deposition architecture in which both vapor sources are physically distinct yet centrally synchronized, allowing precise and reproducible vapor mixing on the substrate surface and uniform composition control across the deposition region.

In certain embodiments, the feed-in subsystem may further include a distribution assembly integrated with the precursor chamber, functioning as a selector or diverter to route precursor materials to multiple crucibles.

In FIG. 14, an embodiment 1400 of a single-manifold, multi-crucible vapor-delivery system is shown. A precursor chamber 1410 receives multiple solid or pelletized precursor materials and meters them sequentially or simultaneously into a series of crucibles 1420-1423, each configured to vaporize an individual constituent material such as copper (Cu), indium (In), gallium (Ga), or selenium (Se). The precursor materials are metered toward a distribution assembly (not visible) that may include a selector or diverter and a set of branch feed passages configured to route material from the precursor chamber 1410 to the series of crucibles 1420-1423. The selector may be implemented as a rotary plug, spool, or multi-port valve operating under vacuum to direct selected materials to designated crucibles while non-selected branches remain isolated or purged. The distribution assembly may employ any suitable selector or diverter mechanism known in the art, such as a heated multi-port valve or powder-feed diverter configured for vacuum operation. In certain embodiments, the precursor chamber 1410 further includes a volumetric screw or vibratory feeder configured to index a defined mass toward the selector; non-selected branches may remain closed and optionally purged.

Each crucible (1420-1423) is disposed in a high-temperature housing and may be operated at a distinct setpoint within a range of about ambient to ≥1600° C. depending on precursor chemistry. For example, crucibles handling Cu, In, and Ga may operate at about 1200-1400° C., while a crucible containing Se may operate at about 250-600° C. The crucibles may include local thermocouples and heater elements connected to a common control unit, similar to that described with respect to FIG. 7, allowing differential setpoints among the crucibles to optimize vaporization rates.

Vaporized precursor from the active crucibles is conveyed into a common heated transfer tube 1440, which merges the vapor streams and delivers them to a manifold 1450. The transfer tube 1440 and manifold 1450 may include temperature-controlled zones to maintain the vapors above condensation temperature and to promote uniform mixing before emission through a nozzle array 1460. The nozzle array 1460 comprises multiple outlets aligned along the substrate width to produce a spatially resolved vapor flux.

In certain embodiments, dopants such as NaF, KF, CsF, and RbF are provided at the substrate such that the deposition from the nozzle array 1460 proceeds over a substrate on which dopant species are already present; the manner by which dopants are provided at or on the substrate is not limited by this disclosure.

Accordingly, FIG. 14 illustrates a single-chamber, multi-crucible architecture in which the precursor chamber 1410 distributes material to multiple crucibles 1420-1423 through the distribution assembly, enabling distinct temperature control for each crucible and combined vapor delivery through the transfer tube 1440, manifold 1450, and nozzle array 1460.

In FIG. 15, an embodiment 1500 is shown that corresponds in structure and function to FIG. 14 with figure-specific numbering. A precursor chamber 1510 receives multiple solid or pelletized precursor materials and meters them toward a distribution assembly. The distribution assembly includes a selector or diverter and a set of branch feed passages configured to route material from the precursor chamber 1510 to a series of crucibles 1520-1527. The selector may be implemented as a rotary plug, spool, or multi-port valve operating under vacuum to direct selected materials to designated crucibles while non-selected branches remain isolated or purged.

Each crucible (1520-1527) is disposed within a high-temperature housing and may be operated at a distinct temperature setpoint within a range of from about ambient to about ≥1600° C., depending on the respective precursor. For example, crucibles containing metallic precursors may operate at from about 1200° C. to about 1400° C., while a crucible containing selenium or dopant compounds may operate at from about 250° C. to about 600° C. Each crucible may incorporate an internal heater and sensor set for closed-loop temperature regulation.

Vaporized precursor material from the active crucibles is conveyed through a heated transfer tube 1540 to a manifold 1550, which distributes the combined vapor flow to a nozzle array 1560. The transfer tube 1540 and manifold 1550 may include temperature-controlled zones to maintain all vapors above condensation temperature and to promote homogeneous mixing before emission through the nozzle array 1560. The nozzle array 1560 includes multiple outlets arranged along the substrate width to produce a spatially resolved vapor flux.

Dopant materials such as NaF, KF, CsF, and RbF may be introduced through one or more of the crucibles 1520-1527, pre-mixed with other feedstocks, or delivered by additional crucibles connected to the same distribution assembly. In certain embodiments, one or more selected dopants are provided at the substrate such that the deposition from the nozzle array 1560 proceeds over a substrate on which dopant species are already present; the manner by which dopants are provided at or on the substrate is not limited by this disclosure.

Accordingly, FIG. 15 illustrates a single-chamber, multi-crucible architecture in which the precursor chamber 1510 distributes material to multiple crucibles 1520-1527 through the distribution assembly, enabling distinct crucible temperature control and combined vapor delivery through the transfer tube 1540, manifold 1550, and nozzle array 1560.

In FIG. 16, an embodiment 1600 of a vapor-delivery system employing multiple manifolds is shown. A precursor chamber 1610 houses a volumetric screw feeder configured to receive and meter multiple precursor materials such as copper (Cu), indium (In), gallium (Ga), and selenium (Se). Each of these materials is directed to a corresponding crucible 1620-1623, one crucible for each precursor species. The crucibles (1620-1623) are positioned within high-temperature housings and may be operated at distinct setpoints ranging from about ambient to about ≥1600° C. depending on the respective precursor. Each crucible may include a local heater and sensor set (e.g., 1624a-1624d) to maintain the vapor phase of each material at its optimal temperature and to provide closed-loop control for stable evaporation rates.

Vaporized materials from the crucibles 1620-1623 are conveyed through individual transfer-tube segments 1630-1633 to corresponding manifolds 1640-1643. Each manifold receives vapor from one crucible and distributes it laterally through a dedicated outlet array that directs the vapor toward the substrate plane. The manifolds (1640-1643) are arranged substantially parallel to each other, with each providing a spatially distinct vapor flux representing a specific precursor composition. The outlet temperature of each manifold may be independently controlled to remain above the condensation threshold of its respective vapor species.

The combined output of the four manifolds forms a composition-controlled vapor field above the substrate region, enabling sequential or simultaneous co-deposition of the four constituent materials onto the moving substrate. In some embodiments, dopant materials such as NaF, KF, RbF, and CsF are introduced by mixing with the metallic or selenium precursors within the crucibles 1620-1623, or by adding one or more additional crucibles and associated manifolds dedicated to dopant sources. Alternatively, dopants may be provided at the substrate such that the deposition from the manifolds proceeds over a substrate surface already containing dopant species. The system may also include more than one precursor chamber 1610, allowing separate feed-in chambers for specific precursor or dopant sets.

Accordingly, FIG. 16 illustrates a multi-manifold vapor-delivery system in which a precursor chamber 1610 supplies multiple crucibles 1620-1623 that are individually heated and independently coupled to corresponding manifolds 1640-1643, thereby producing multiple vapor streams of differing composition that combine or overlap at the substrate surface for controlled thin-film deposition.

In another embodiment, one or more crucibles of the deposition system contain silver (Ag) and/or sulfur(S) precursors in addition to the metallic and chalcogen components previously described. The Ag and S sources may be introduced as elemental, sulfide, selenide, or halide compounds and are vaporized under controlled temperatures ranging from about 250° C. to about 1400° C. depending on composition. These vapors may combine with Cu, In, Ga, and Se species within the transfer tube or manifold to form Ag—(Cu, In, Ga)—(S, Se) alloys or related multichalcogenide films.

In a further embodiment, the system of Embodiment 1 is supplemented by the introduction of alkali-metal dopants selected from sodium (Na), potassium (K), cesium (Cs), rubidium (Rb), and lithium (Li). Each alkali precursor may be supplied in a separate crucible or mixed with a metallic or chalcogen feedstock. The alkali species may be provided as fluorides, carbonates, oxides, or selenides and vaporized at temperatures from about 250° C. to about 600° C. The presence of these dopants enhances grain growth and electrical conductivity in the deposited films.

In another embodiment, the deposition system further comprises one or more low-temperature crucibles configured to vaporize hybrid-organic halide precursors such as methylammonium lead iodide (CH₃NH₃PbI₃, MAPbI₃), methylammonium lead mixed iodide-bromide [CH₃NH₃Pb(I₁₋ₓBrₓ)₃], methylammonium lead chloride (CH₃NH₃PbCl₃), methylammonium lead bromide (CH₃NH₃PbBr₃), methylammonium tin iodide (CH₃NH₃SnI₃), methylammonium tin chloride (CH₃NH₃SnCl₃), methylammonium tin bromide (CH₃NH₃SnBr₃), formamidinium lead iodide (HC(NH₂)₂PbI₃, FAPbI₃), formamidinium lead chloride (FAPbCl₃), formamidinium lead bromide (FAPbBr₃), formamidinium tin iodide (FASnI₃), formamidinium tin chloride (FASnCl₃), and formamidinium tin bromide (FASnBr₃). These hybrid perovskite and tin-halide compounds are introduced as vaporized or sublimed species from crucibles operated at about 150° C. to about 400° C. and may be co-deposited with metallic and chalcogen vapors to form composite or layered perovskite-chalcogenide structures.

What is claimed is:

1) A vapor deposition system comprising:
a feed-in subsystem configured to deliver precursor material to a crucible under vacuum conditions, the feed-in subsystem including a feed-in chamber, a high-temperature valve, and a feed-in tube forming a vapor-tight connection to the crucible;
the crucible disposed within a crucible housing and configured to vaporize the precursor material;
a transfer-tube and manifold assembly fluidly coupled to the crucible; and
a nozzle array coupled to the manifold and configured to direct vaporized precursor material toward a substrate.

2) The system of claim 1, wherein the crucible is configured to operate at temperatures of at least about 1400° C., and in other embodiments operable from about ambient temperature up to about 1600° C. depending on the precursor material.

3) The system of claim 1, wherein the manifold comprises a plurality of outlets arranged in a spatially resolved pattern configured to regulate vapor flux uniformity across the substrate, thereby maintaining film-thickness uniformity within about or better than ±(3-4)% across substrates having widths of about 1216 mm and within about or better than ±2% across substrates having widths of about 300 mm.

4) The system of claim 1, further comprising a transfer tube extending laterally between the crucible and the manifold, the transfer tube being heated to maintain the vaporized precursor material above a condensation temperature.

5) The system of claim 1, wherein the feed-in tube includes one or more internal helical shields or staggered inclined baffles configured to permit precursor solids to pass downward while impeding upward thermal flux and back streaming of vapor.

6) The system of claim 1, wherein the feed-in subsystem further comprises purge-gas conduits configured to introduce an inert gas sweep along an inner liner of the feed-in tube to impede condensation and back streaming of vapor, and wherein the feed-in chamber is reloadable with precursor material without disrupting vacuum integrity downstream of the high-temperature valve.

7) The system of claim 1, wherein the crucible comprises graphite, boron nitride, mullite, or pyrolytic boron nitride, and a transfer-tube and manifold assembly comprises graphite, boron nitride, pyrolytic boron nitride, coated graphite, mullite, alumina, zirconia, aluminum nitride, or a refractory metal with a corrosion-resistant coating.

8) The system of claim 1, further comprising an inner shield surrounding the transfer-tube and manifold assembly and a cooling jacket surrounding the inner shield, the cooling jacket circulating a high-temperature heat-transfer fluid or chilled water between about −20° C. and about 150° C. at a flow rate exceeding about 4 gallons per minute.

9) The system of claim 8, further comprising an outer shield tube enclosing the transfer-tube and manifold assembly and coupled to a flange for chamber mounting, and in some embodiments an exoskeleton enclosing the crucible, transfer tube, manifold, and nozzle array, the exoskeleton including cooling jackets integrated into its walls.

10) The system of claim 1, wherein one or more internal surfaces of the crucible, manifold, shield, or feed-in tube include a boron-nitride coating configured to resist degradation by selenium-containing vapors.

11) The system of claim 1, wherein a proximal segment of a transfer-tube and manifold assembly adjacent the crucible is maintained at a temperature sufficient to keep the precursor material in a vapor phase along the transfer region; and wherein a distal nozzle-array region is maintained at a temperature sufficient to inhibit condensation at or adjacent to outlets of the nozzle array.

12) The system of claim 1, wherein the transfer-tube and manifold assembly comprises a closed-loop temperature-control system configured to maintain the assembly at a temperature sufficient to maintain the precursor material in a vapor phase and to inhibit condensation along an interior surface of the vapor path, with a control accuracy of about ±0.5° C.

13) The system of claim 1, wherein a flange joint between the crucible housing and the transfer-tube and manifold assembly includes a projecting spigot and a corresponding counterbore configured to provide radial alignment and transfer mechanical loads at elevated temperature, and further comprises a bellows at the flange joint configured to accommodate differential thermal expansion while preserving vacuum integrity.

14) The system of claim 1, wherein the feed-in chamber provides a total volume of about 2000 cc with a net capacity of about 1200 cc for substrates of about 300 mm width, or provides a total volume of about 8000 cc with a net capacity of about 4800 cc for substrates of about 1216 mm width.

15) The system of claim 1, wherein the feed-in tube has a length greater than about 6 inches and an internal diameter greater than about 1 inch.

16) The system of claim 3, wherein the nozzle array comprises about 10 to about 40 nozzles each having a diameter in a range from about 3 mm to about 10 mm and spaced at intervals from about 20 mm to about 40 mm, and for a substrate width of about 1216 mm comprises about 31 nozzles each having a diameter of about 8 mm and spaced at about 40 mm, while for a substrate width of about 300 mm comprises about 11 nozzles each having a diameter of about 3.5 mm.

17) The system of claim 16, wherein the nozzles are oriented substantially perpendicular to the substrate, and in other embodiments one or more nozzles are angled relative to the substrate to tailor flux distribution; and wherein the nozzle-to-substrate distance is in a range from about 75 mm to about 200 mm.

18) The system of claim 1, wherein at least one crucible contains a silver (Ag) or sulfur (S) precursor.

19) The system of claim 18, wherein the system further includes one or more alkali-metal dopants selected from sodium, potassium, cesium, rubidium, and lithium.

20) The system of claim 19, wherein the system further includes one or more low-temperature crucibles configured to vaporize hybrid-organic halide precursors selected from methylammonium lead halides, methylammonium tin halides, formamidinium lead halides, and formamidinium tin halides.
